(19) United States
(12) Patent Application Publication
(10) Pub. No.: US 2017/0279042 A1
(43) Pub. Date: Sep. 28, 2017

(54) FAST ERASING MEMRISTORS

(71) Applicant: HEWLETT-PACKARD DEVELOPMENT COMPANY, L.P., Houston, TX (US)

(72) Inventors: Ning GE, Palo Alto, CA (US); Jianhua YANG, Palo Alto, CA (US); Minxian ZHANG, Mountain View, CA (US)

(73) Assignee: HEWLETT-PACKARD DEVELOPMENT COMPANY, L.P., Houston, TX (US)

(21) Appl. No.: 15/507,014

(22) PCT Filed: Aug. 29, 2014
(86) PCT No.: PCT/US2014/053324

§ 371 Date: Feb. 27, 2017

(51) Int. Cl. H01L 45/00

(52) U.S. Cl. CPC H01L 45/08; H01L 45/1286; H01L 45/1233; H01L 45/146

(57) ABSTRACT

A fast erasing memristor includes an active region, a resistive heater, and a dielectric sheath. The active region has a switching layer coupled between a first conducting layer and second conducting layer. The resistive heater is coupled to the active region to provide heat to the active region. The dielectric sheath separates the active region and the resistive heater.

### BACKGROUND

Memristors are devices that can be programmed to different resistive states by applying a programming energy, such as a voltage. After programming, the state of the memristor can be read and remains stable over a specified time period. Thus, memristors can be used to store digital data. For example, a high resistance state can represent a digital “0” and a low resistance state can represent a digital “1.” Large crossbar arrays of memristive elements can be used in a variety of applications, including random access memory, non-volatile solid state memory, programmable logic, signal processing control systems, pattern recognition, and other applications.

### BRIEF DESCRIPTION OF THE DRAWINGS

The following detailed description references the drawings, wherein:

FIG. 1A is a cross-sectional view of an example fast erasing memristor;

FIG. 1B is a cross-sectional view of a switching layer of an active region of an example fast erasing memristor;

FIG. 1C is a cross-sectional view of an active region of an example fast erasing memristor in an insulating state;

FIG. 1D is a cross-sectional view of an active region of an example fast erasing memristor in a conducting state;

FIG. 2 is a cross-sectional view of an example fast erasing memristor having two sets of electrodes and an active region that encloses a portion of a resistive heater;

FIG. 3 is a top-down view of an example fast erasing memristor;

FIG. 4 is a diagram of an example integrated circuit having a fast erasing memristor; and

FIG. 5 is a flowchart of an example method for erasing a memristor.

### DETAILED DESCRIPTION

Memristors are devices that may be used as components in a wide range of electronic circuits, such as memories, switches, radio frequency circuits, and logic circuits and systems. In a memory structure, a crossbar array of memristive devices may be used. When used as a basis for memories, memristors may be used to store bits of information, 1 or 0. When used as a logic circuit, a memristor may be employed as configuration bits and switches in a logic circuit that resembles a Field Programmable Gate Array, or may be the basis for a wired-logic Programmable Logic Array. It is also possible to use memristors capable of multi-state or analog behavior for these and other applications.

The resistance of a memristor may be changed by applying an electrical stimulus, such as a voltage or a current, through the memristor. Generally, at least one channel may be formed that is capable of being switched between two states—one in which the channel forms an electrically conductive path (“ON”) and one in which the channel forms a less conductive path (“OFF”). In some other cases, conductive paths represent “OFF” and less conductive paths represent “ON”. Conducting channels may be formed by ions and/or vacancies. Some memristors exhibit bipolar switching, where applying a voltage of one polarity may switch the state of the memristor and where applying a voltage of the opposite polarity may switch back to the original state. Alternatively, memristors may exhibit unipolar switching, where switching is performed, for example, by applying different voltages of the same polarity.

In order to switch a memristor, an electrical stimulus may be applied to that memristor. In some examples, switching a memristor from an OFF state to an ON state may be referred to as writing. On the other hand, switching a memristor from an ON state to an OFF State may be referred to as erasing. In many existing implementations, each memory cell must be written or erased individually. However, in some applications, such as in the use of memristors on printheads, a high memory refresh speed is desired. For example, it may be desirable to reset, such as by erasing, an entire array of memory cells before reprogramming the array.

Examples herein provide for fast erasing memristors. In example implementations, a fast erasing memristor has an active region, which includes a switching layer coupled between a first conducting layer and a second conducting layer; a resistive heater coupled to the active region to provide heat to the active region; and a dielectric sheath separating the active region and the resistive heater. The heat provided by the resistive heater may thermally anneal the switching layer of the active region. Thermally annealing the switching layer may switch the switching layer, for example, from an ON state to an OFF state. By using thermal anneal to switch a memristor, multiple memory cells of a large crossbar array may be refreshed or reset simultaneously. Accordingly, fast erasing memristors may be used, for example, in applications calling for memories with high refresh speeds.

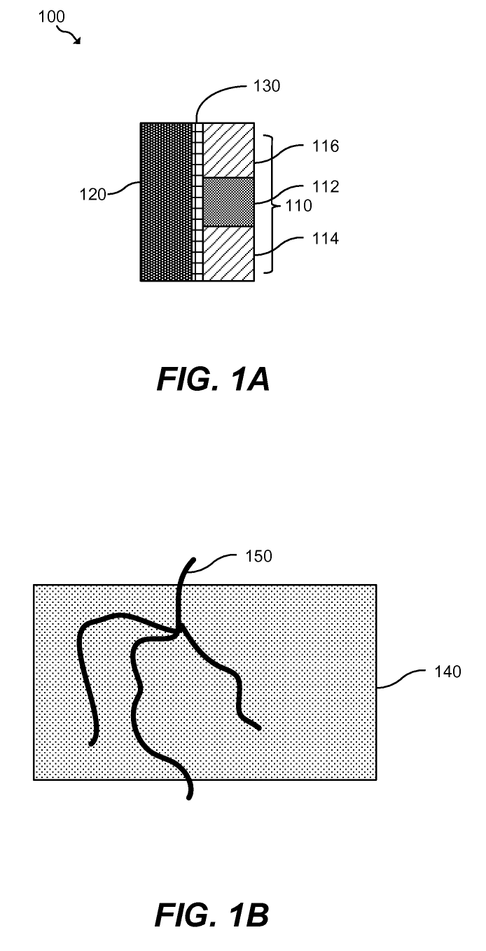

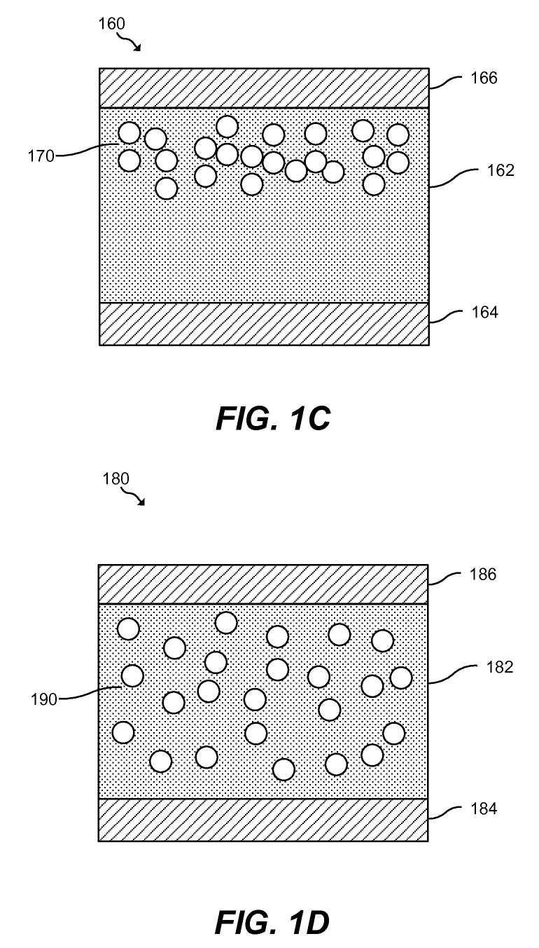

Referring now to the figures, FIG. 1 A depicts a cross-sectional view of an example fast erasing memristor 100. Fast erasing memristor 100 may have an active region 110, a resistive heater 120, and a dielectric sheath 130. Active region 110 may include a switching layer 112 coupled between a first conducting layer 114 and a second conducting layer 116. Resistive heater 120 may be coupled to active region 110 to provide heat to active region 110. Dielectric sheath 130 may separate active region 110 and resistive heater 120.

Fast erasing memristor 100 may be an electrical device having active region 110 with switching layer 112 that has a resistance that changes with an applied electrical stimulus, such as a voltage, current, or other electrical stimulation. For example, the application of a voltage across fast erasing memristor 100 may switch fast erasing memristor 100 from a first state to a second state. Furthermore, fast erasing memristor 100 may “memorize” its last resistance. In this manner, fast erasing memristor 100 may be set to at least two states. Fast erasing memristor 100 may form the basis for memory cells in a larger structure, such as a crossbar array. For example, each fast erasing memristor 100 may form a single memory cell in an array.

Active region 110 may be the region within fast erasing memristor 100 that provides the switching properties. Active region 100 may have a switching layer 112 coupled between a first conducting layer 114 and a second conducting layer 116. Coupling the layers may form a continuous electrical path so current may travel through first conducting layer 114, switching layer 112, and second conducting layer 116. For example, the layers may be coupled by forming direct, surface contacts between two layers. Active region 110 may be based on a variety of materials. Switching layer 112 may have a material with switching behavior. In some examples, switching layer 112 may be oxide-based, meaning that at least a portion of the layer is formed from an oxide-containing material. Switching layer 112 may also be nitride-based, meaning that at least a portion of the layer is formed from a nitride-containing composition. Furthermore, switching layer 112 may be oxy-nitride based, meaning that a portion of the layer is formed from an oxide-containing material and that a portion of the layer is formed from a nitride-containing material. In some examples, switching layer 112 may be formed based on tantalum oxide (TaOₓ) or hafnium oxide (HfOₓ) compositions. Other example materials may include titanium oxide, yttrium oxide, niobium oxide, zirconium oxide, aluminum oxide, calcium oxide, magnesium oxide, dysprosium oxide, lanthanum oxide, silicon dioxide, or other like oxides. Further examples include nitrides, such as aluminum nitride, gallium nitride, tantalum nitride, and silicon nitride.

On the other hand, first conducting layer 114 and second conducting layer 116 may have electrically conducting materials. Some example materials for first conducting layer 114 and second conducting layer 116 may include a metal such as platinum (Pt), tantalum (Ta), hafnium (Hf), zirconium (Zr), aluminum (Al), cobalt (Co), nickel (Ni), iron (Fe), niobium (Nb), molybdenum (Mo), tungsten (W), copper (Cu), or titanium (Ti), or an electrically conducting metal nitride, such as TiNₓ or TaNₓ. In some implementations, first conducting layer 114 and second conducting layer 116 may include the same material. For example, both may be tantalum nitride. Alternatively, first conducting layer 114 and second conducting layer 116 may have different materials.

Resistive heater 120 may be coupled to active region 110 and may provide heat to thermally anneal switching layer 112 of active region 110. For example, resistive heater 120 may be a resistor that experiences joule heating when an electrical stimulus, such as a current, is passed through it. In particular, resistive heater 120 may heat active region 110 to a particular annealing temperature range for a particular annealing time period, in order to promote switching of switching layer 112 from the second state to the first state or from the first state to the second state. The particular annealing temperature range and the particular annealing time period may be predetermined to adequately promote switching of switching layer 112. In some examples, resistive heater 120 may have titanium nitride or other compounds or alloys with high resistivity.

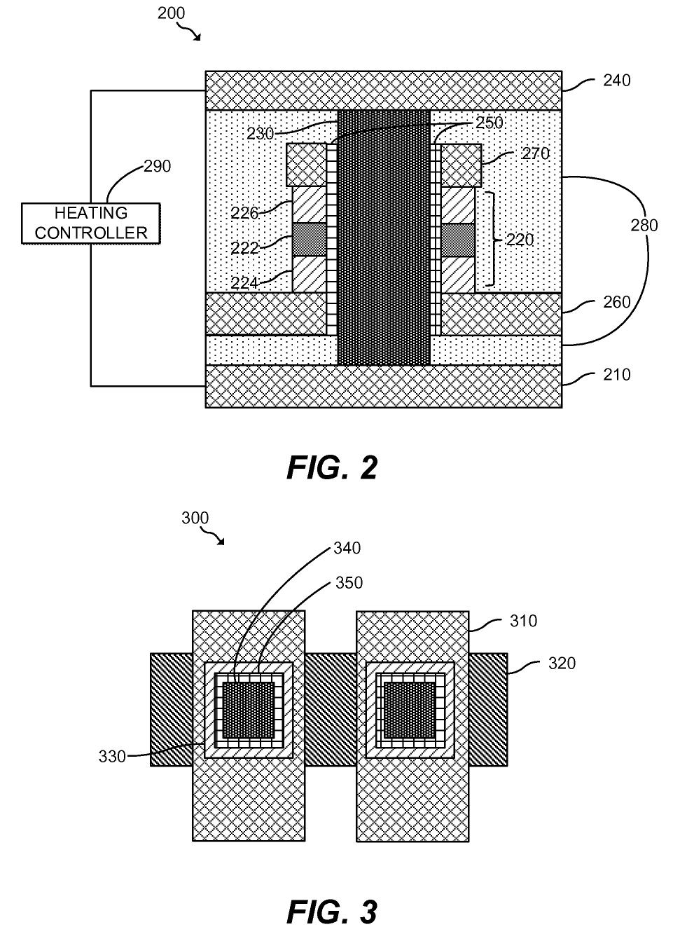

Resistive heater 120 may be positioned in various configurations in relation to active region 110. In the example shown in FIG. 1A, resistive heater 120 is coupled adjacent to active region 110. In other words, resistive heater 120 is in parallel with active region 110. Alternatively, resistive heater 120 may be placed in series with active region 110, such as either above or below active region 110. Furthermore, resistive heater 120 may enclose a part or all of active region 110. Alternatively, resistive heater 120 may be plugged-in active region 110. In other words, active region 110 may enclose at least a portion of resistive heater 120. Further details of the orientation of resistive heater 120 are discussed herein in reference to FIG. 2.

Dielectric sheath 130 may separate active region 110 and resistive heater 120. In some examples, dielectric sheath 130 may be thermally conducting. A thermally conducting dielectric sheath 130 may effectuate transfers of heat from resistive heater 120 to active region 110 in order to thermally anneal switching layer 112. Generally, dielectric sheath 130 may have a material that is chemically inert to the materials of active region 110 and the materials of resistive heater 120 to mitigate reactions between the components. In addition, dielectric sheath 130 may have an electrically insulating material, particularly a material with a low dielectric constant, in order to electrically insulate active region 110 and resistive heater 120. During operation, current may travel through active region 110 to read or write switching layer 112. During refresh, current may travel through resistive heater 120 to produce heat. Without electrical isolation, current may travel between active region 110 and resistive heater 120 and cause issues, such as short circuit. Non-limiting example materials for dielectric sheath 130 may include oxides, nitrides, and carbon-doped materials.

FIG. 1B depicts a cross-section view of an example switching layer 140 of an active region of an example fast erasing memristor, such as example fast erasing memristor 100 of FIG. 1A. Switching layer 140 may be analogous to switching layer 112 of active region 110 as depicted in and described in reference to FIG. 1A. In some examples, switching layer 140 may have a first electrical state. For example, the first electrical state may be relatively insulating. When an electrical stimulus, such as a voltage, is applied, switching layer 140 may form a current channel 150. While FIG. 1B shows one current channel 150 formed through switching layer 140, it should be noted that there may be multiple current channels formed, some of which may extend through all of switching layer 140 and some of which may terminate within switching layer 140. Applying an electrical stimulus to switching layer 140 may cause switching layer 140 to have a second state, where the second state may, for example, be relatively conducting. Alternatively, in some examples, the first state may be relatively conducting, and the second state may be relatively insulating.

FIG. 1C depicts a cross-sectional view of an example active region 160 of an example fast erasing memristor, such as example fast erasing memristor 100 of FIG. 1A, in an insulating state. Active region 160 may be analogous to active region 110 as depicted in and described in relation to FIG. 1A. Active region 160 may have a switching layer 162 coupled between a first conducting layer 164 and a second conducting layer 166. In some examples, dopants 170 may be distributed within switching layer 162. As shown in FIG. 1C, dopants 170 may be concentrated towards one end of switching layer 162 when active region 160 is in an insulating state.

Dopants 170 may be a substance that is inserted into a medium in order to alter the electrical properties of the medium. For example, dopants 170 may be impurities, ions, or vacancies that may alter, such as increase, the electrical conductivity of the medium. Dopants 170 may facilitate the formation of current channels, such as current channel 150 of FIG. 1B, by conducting current through switching layer 162. In some examples, dopants 170 may be concentrated towards one end of switching layer 162. In such configurations, active region 160 may be relatively insulating because the distribution of dopants 170 towards one end of switching layer 162 does not effectively create current channels through the layer. However, applying an electrical stimulus through active region 160 may switch active region 160 from a first state to a second state. In some examples, the first state may be a relatively insulating state, and the second state may be a relatively conducting state. In other examples, the opposite may be true.

FIG. 1D depicts a cross-sectional view of an example active region 180 of an example fast erasing memristor, such as example fast erasing memristor 100 of FIG. 1A, in a conducting state. Active region 160 may be analogous to active region 160 of FIG. 1C or active region 110 of FIG. 1A. Active region 180 may have a switching layer 182 coupled between a first conducting layer 184 and a second conducting layer 186. Dopants 190 may be distributed relatively uniformly throughout switching layer 182 when active region 180 is in a conducting state. The relatively uniform distribution of dopants 190 throughout switching layer 182 may effectively facilitate the formation of current channels through switching layer 182.

In some examples, thermally annealing active region 180 switches switching layer 182. Specifically, thermal anneal may cause dopants 190 to migrate within switching layer 182. For example, dopants 190 may tend to converge near one end of switching layer 182 under the influence of heat. Therefore, thermal anneal may cause active region 180 to switch from the electrically conducting state depicted in FIG. 1D to the electrically insulating state of FIG. 1C. Alternatively, in other examples, thermally annealing switching layer 182 may promote the dispersion of dopants 190 throughout switching layer 182. In such instances, thermal anneal may cause active region 180 to switching from the electrically insulating state of FIG. 1C to the electrically conducting state of FIG. 1D.

FIG. 2 depicts a cross-sectional view of an example fast erasing memristor 200 having two sets of electrodes and an active region 220 that encloses a portion of a resistive heater 230. Active region 220 may include a switching layer 222 coupled between a first conducting layer 224 and a second conducting layer 226. Resistive heater 230 may be coupled to active region 220 to provide heat to active region 220. Furthermore, a dielectric sheath 250 may separate active region 220 and resistive heater 230.

In some examples, such as the one illustrated in FIG. 2, at least a portion of active region 220 encloses at least a portion of resistive heater 230. In one example, active region 220 surrounds resistive heater 230. In other words, resistive heater 230 may be plugged-in to or penetrates through the length of active region 220. Such a structure may be formed, for example, by forming active region 220, using a process such as deposition, by opening a hole through the body of active region 220, and by then forming resistive heater 230 within the hole. In some examples, dielectric sheath 250 may be formed prior to forming resistive heater 230 in order to create the separation between resistive heater 230 and active region 220. Such a configuration may increase the heating efficiency of resistive heater 230 as well as minimize the effective size of active region 220, which allows the operation of fast erasing memristor 200 at operating currents.

Fast erasing memristor 200 may also include a first electrode 210 coupled to a first end of resistive heater 230, a second electrode 240 coupled to a second end of resistive heater 230, a third electrode 260 coupled to first conducting layer 224 of active region 220, and a fourth electrode 270 coupled to second conducting layer 226 of active region 220. These electrodes may be electrically conducting, and first electrode 210 and second electrode 240 may form a first set of electrodes that may carry an electrical stimulus to resistive heater 230. For example, an applied voltage may drive a current along first electrode 210, through resistive heater 230, and along second electrode 240. Furthermore, first electrode 210 and second electrode 240 may serve as connections for resistive heater 230 to other components in an array. For example, multiple resistive heaters 230 may be connected to the same first electrode 210 and second electrode 240 in a crossbar array. In such examples, applying an electrical stimulus to first electrode 210 or second electrode 240 or both may drive the electrical stimulus to multiple resistive heaters 230, which may allow switching of multiple fast erasing memristors 200 by thermal anneal.

On the other hand, third electrode 260 and fourth electrode 270 may form a second set of electrodes that may carry an electrical stimulus to active region 220. For example, an applied voltage may drive a current along third electrode 260, through active region 220, and along fourth electrode 270. The current may be used to read the resistive state of active region 220, or it may switch switching layer 222. Furthermore, third electrode 260 and fourth electrode 270 may serve as connections for active region 220 to other components in an array, such as other active regions in a crossbar. The first to fourth electrodes described herein may include a number of conducting materials. Non-limiting example materials include Pt, Ta, Hf, Zr, Al, Co, Ni, Fe, Nb, Mo, W, Cu, Ti, TiN, TaN, Ta₂N, WN₂, NbN, MoN, TiSi₂, TiSi, Ti₅Si₃, TaSi₂, WSi₂, NbSi₂, V₃Si, electrically doped polycrystalline Si, electrically doped polycrystalline Ge, and combinations thereof.

In some examples, resistive heater 230 may be coupled to at least a portion of each layer of active region 220, and resistive heater 230 may extend beyond both ends of active region 220. Such a structure may allow the separation of the first set of electrodes and the second set of electrodes. Separating the electrodes may prevent short circuits and other interference between the electrodes. Furthermore, fast erasing memristor 200 may have an interlayer dielectric 280 that serves to separate the non-coupled components. Interlayer dielectric 280 may be, for example, an electrically insulating material, such as oxides or nitrides.

Additionally, in some implementation, fast erasing memristor 200 may have a heating controller 290 to control application of an electrical stimulus to resistive heater 230. Heating controller 290 may be a device or component that, in addition to other functions, operates or controls the heating of resistive heater 230 by driving electrical stimulus to the resistive heater. The implementation of heating controller 290 may include hardware-based components, such as a microchip, chipset, or electronic circuit, and software-driven components, such as a processor, microprocessor, or some other programmable device. In some examples, heating controller 290 may be a circuit having a multiplexer that may direct voltage or current to electrodes, such as first electrode 210 and second electrode 240.

FIG. 3 depicts a top-down view of an example fast erasing memristor 300. For example, fast erasing memristor 300 may be similar to example fast erasing memristor 200 as depicted in and described in relation to FIG. 2. Fast erasing memristor 300 may have a first electrode 310, a second electrode 320, an active region 330, a resistive heater 340, and a dielectric sheath 350. The structure of active region 330, heater 340, and dielectric sheath 350 is shown for illustration purposes. In some examples, first electrode 310 may cover the top of at least active region 330. Additionally, fast erasing memristor 300 may have additional electrodes coupled to resistive heater 340 that are separated from first electrode 310 and second electrode 320. Such example structures have been described in detail above.

As shown in FIG. 3, active region 330 may surround resistive heater 340. Dielectric sheath 350 may separate active region 330 from resistive heater 340. As detailed above, such separation may prevent chemical and electrical interference between active region 330 and resistive heater 340. Dielectric sheath 350 may, however, be thermally conducting to promote heating of active region 330 by the heat provided by resistive heater 340. While FIG. 3 shows active region 330, resistive heater 340, and dielectric sheath 350 to have polygonal shapes, these components and others may take on various configurations and structures.

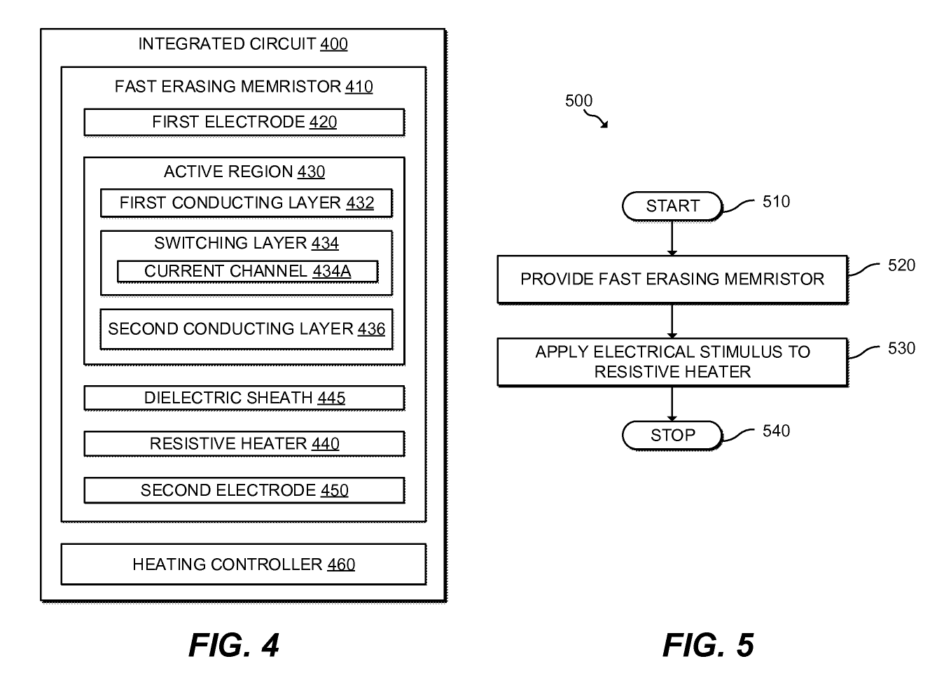

FIG. 4 depicts a diagram of an example integrated circuit 400 having a fast erasing memristor 410. Integrated circuit 400 may be a device having sets of circuits that operate using fast erasing memristors. For example, integrated circuit 400 may have one or more large crossbar arrays of fast erasing memristors 400 and other electronic components on a chip of semiconductor material, such as silicon. Integrated Circuit 400 may be used in a variety of applications, including in memory devices and as components on printheads.

Fast erasing memristor 410 may be similar to fast erasing memristor 100 of FIG. 1A, fast erasing memristor 200 of FIG. 2, or fast erasing memristor 300 of FIG. 3. Fast erasing memristor 410 may include a first electrode 420, an active region 430, a resistive heater 440, a dielectric sheath 445, and a second electrode 450. First electrode 420 and second electrode 450 may connect fast erasing memristor 410 to other components within integrated circuit 400, such as other memristors in an array or to heating controller 460. The electrodes may carry electrical stimulus to active region 430 which may provide the memristive properties of fast erasing memristor 410. Active region 430 may include a first conducting layer 432, a switching layer 434, and a second conducting layer 436. As described herein, switching layer 434 exhibit switching properties and may form one or more current channels 434A.

Resistive heater 440 may be coupled to active region 430 to provide heat to active region 430. Providing heat to active region 440, and specifically switching layer 434, may thermally anneal switching layer 434. Thermal annealing switching layer 434 may cause switching of the layer from one state to another. For example, heating switching layer 434 may switch it from an electrically conducting state to an insulating state, or vice versa. Specifically, for example, thermal anneal may cause the formation or destruction of current paths in switching layer 434, thus influencing its electrical state. Additionally, a dielectric sheath 445 may separate active region 430 and resistive heater 440. As described herein, dielectric sheath 445 may electrically and chemically insulate active region 430 from resistive heater 440 and vice versa. Furthermore, integrated circuit 400 may have a heating controller 460. As described herein, heating controller 460 may be a device or component that, in addition to other functions, operates or controls the heating of resistive heater 440 by driving electrical stimulus to the resistive heater.

FIG. 5 depicts a flowchart of an example method 500 for erasing a memristor. Method 500 may include block 520 for providing a fast erasing memristor and block 530 for applying an electrical stimulus to a resistive heater of the fast erasing memristor. Although execution of method 500 is herein described in reference to fast erasing memristor 100 of FIG. 1A, other suitable parties for implementation of method 500 should be apparent, including fast erasing memristor 200 of FIG. 2 and fast erasing memristor 300 of FIG. 3.

Method 500 may start in block 510 and proceed to block 520, where a fast erasing memristor, such as fast erasing memristor 100, is provided. Fast erasing memristor 100 may have an active region 110 which may provide memristive properties. Active region 110 may include a switching layer 112 coupled between a first conducting layer 114 and a second conducting layer 116. Switching layer 112 may provide switching, as described in detail herein. Fast erasing memristor 100 may also have a resistive heater 120 coupled to active region 110 to provide heat to the active region. Resistive heater 120 may be a resistive material that may provide heat, such as by joule heating. Furthermore, fast erasing memristor 100 may include a dielectric sheath 130 separating active region 110 and resistive heater 120. Dielectric sheath 130 may be an electrically insulating material and may be chemically inert to the materials of active region 110 and resistive heater 120. However, dielectric sheath 130 may be thermally conducting to allow the transfer of heat from resistive heater 120 to active region 110.

After providing a fast erasing memristor, method 500 may proceed to block 530, where an electrical stimulus may be applied to resistive heater 120. As described herein, the electrical stimulus may be current, voltage, or other form of electrical stimulation. The electrical stimulus may cause joule heating of resistive heater 120. The heat may be transferred to active region 110, which may cause thermal anneal of switching layer 112 of active region 110. As described herein, thermal annealing switching layer 112 may cause switching of the layer from one state to another. For example, thermal annealing switching layer 112 may switch it from an electrically conducting state to an electrically insulating state, or vice versa. After applying the electrical stimulus, method 500 may proceed to block 540, wherein method 500 may stop.

The foregoing describes a number of examples for fast erasing memristors. It should be understood that the fast erasing memristors described herein may include additional components and that some of the components described herein may be removed or modified without departing from the scope of the fast erasing memristors or its applications. It should also be understood that the components depicted in the figures are not drawn to scale and thus, the components may have different relative sizes with respect to each other than as shown in the figures.

What is claimed is:

1. A fast erasing memristor, comprising:
an active region comprising an switching layer coupled between a first conducting layer and a second conducting layer;
a resistive heater coupled to the active region to provide heat to the active region; and
a dielectric sheath separating the active region and the resistive heater.

2. The fast erasing memristor of claim 1, wherein the switching layer of the active region switches from a first state to a second state when an electrical stimulus is applied.

3. The fast erasing memristor of claim 2, wherein the heat provided by the resistive heater thermally anneals the switching layer of the active region, wherein thermally annealing the switching layer switches the switching layer from the second state to the first state.

4. The fast erasing memristor of claim 1, wherein at least a portion of the active region encloses at least a portion of the resistive heater.

5. The fast erasing memristor of claim 4, wherein the resistive heater is coupled to at least a portion of each layer of the active region, and wherein the resistive heater extends beyond both ends of the active region.

6. The fast erasing memristor of claim 1, wherein the dielectric sheath is thermally conducting, and wherein the dielectric sheath is electrically insulating.

7. The fast erasing memristor of claim 1, further comprising:
a first electrode coupled to a first end of the resistive heater;
a second electrode coupled to a second end of the resistive heater;
a third electrode coupled to the first conducting layer of the active region; and
a fourth electrode coupled to the second conducting layer of the active region.

8. The memristor of claim 1, comprising an interlayer dielectric material electrically insulating non-coupled components of the fast erasing memristor.

9. The memristor of claim 1, comprising a heating controller to control application of an electrical stimulus to the resistive heater.

10. An integrated circuit, comprising fast erasing memristors, and wherein each fast erasing memristor comprises:
an active region comprising a switching layer coupled between a first conducting layer and a second conducting layer;
a resistive heater coupled to the active region to provide heat to the active region; and
a dielectric sheath separating the active region and the resistive heater.

11. The integrated circuit of claim 10, wherein:
the switching layer of the active region switches from a first state to a second state when an electrical stimulus is applied; and
the heat provided by the resistive heater thermally anneals the switching layer of the active region, wherein thermally annealing the switching layer switches the switching layer from the second state to the first state.

12. The integrated circuit of claim 10, wherein:
at least a portion of the active region encloses at least a portion of the resistive heater;
the resistive heater is coupled to at least a portion of each layer of the active region; and
wherein the resistive heater extends beyond both ends of the active region.

13. The integrated circuit of claim 10, comprising a heating controller to control application of an electrical stimulus to the resistive heater.

14. A method for erasing a memristor, comprising:
providing a fast erasing memristor, wherein the fast erasing memristor comprises:
an active region comprising a switching layer coupled between a first conducting layer and a second conducting layer;
a resistive heater coupled to the active region to provide heat to the active region; and
a dielectric sheath separating the active region and the resistive heater; and
applying an electrical stimulus to the resistive heater.

15. The method of claim 14, wherein the heat provided by the resistive heater thermally anneals the switching layer of the active region.
